(19) United States
(12) Patent Application Publication
(10) Pub. No.: US 2007/0222532 A1
(43) Pub. Date: Sep. 27, 2007

(54) Temperature-compensated crystal oscillator

(76) Inventors: Hisato Takeuchi, Kanagawa (JP); Keigo Shingu, Tokyo (JP); Kei Nagatomo, Kanagawa (JP)

Correspondence Address: MCDERMOTT WILL & EMERY LLP, 600 13TH STREET, NW, WASHINGTON, DC, 20005-3096, US

(21) Appl. No.: 11/714,834

(22) Filed: Mar. 7, 2007

(30) Foreign Application Priority Data
Mar. 8, 2006 (JP) 2006-062997

(51) Int. Cl. H03L 1/00

(52) U.S. Cl. 331/176

(57) ABSTRACT

There is provided a temperature-compensated crystal oscillator for reducing a voltage noise of a cubic function control voltage controlling an output frequency of an oscillation circuit.

A temperature-compensated crystal oscillator includes a quartz vibrator, an amplifier having an oscillation frequency controller, and a temperature compensation circuit of a crystal oscillation frequency, wherein a reference voltage for a compensation voltage of the temperature compensation circuit is generated using a forward voltage of a diode.

### BACKGROUND OF THE INVENTION

1. Field of the Invention

The present invention relates to a temperature-compensated crystal oscillator employing a voltage controlled capacitance element.

2. Description of the Related Art

It is known that an oscillation frequency of a known crystal oscillation circuit varies in the form of a cubic function with a variation in temperature due to a physical structure of a quartz vibrator. A current temperature-compensated crystal oscillator (hereinafter, referred to as “TCXO”) primarily employs a current proportional to a band gap reference Vt or a temperature characteristic of a resistor, as a temperature sensor. A cubic function characteristic is implemented using the temperature sensor. For example, in circuits disclosed in Patent Document 1 and Patent Document 2, a voltage acquired by dividing a voltage of a regulator by resistance is used as a reference at the time of synthesizing a current and a voltage generated by the temperature sensor into the cubic function.

FIG. 14 is a diagram illustrating an example of the known TCXO. In a configuration of FIG. 14, a current acquired by subtracting a constant current ICONST from the current (i.e., a current proportional to the temperature) proportional to the band gap voltage Vt is converted into a voltage and the voltage is adjusted so as to output a bias suitable for a crystal.

FIG. 15 is a diagram illustrating another example of the known TCXO. In the TCXO of FIG. 15, the temperature sensor includes two resistors having different temperature coefficients. In the TCXO, a linear function characteristic and the linear function characteristic plus the cubic function characteristic are acquired with a sensor current by using a temperature sensor 1, a linear function circuit 2, and a cubic function circuit 3. The voltage acquired by dividing the voltage of the regulator by resistance is buffered by a reference buffer amplifier 4 to generate a reference of a control voltage and the temperature sensor current is converted into the voltage by using the resistor to adjust the voltage so as to output the bias suitable for the crystal.

Patent Document 1: Pages 5 to 12 and FIG. 1 in Japanese Examined Patent Application Publication No. 3129974

Patent Document 2: Pages 6 to 9 and FIG. 1 shown in Japanese Examined Patent Application Publication No. 3129240

However, there are two types of phase noises of TCXO, and the noise of TCXO is determined by the sum of the two types of phase noises. One is a phase noise of a single oscillation circuit including an oscillation control element and the other is a voltage noise of a cubic function control voltage controlling an output frequency of the oscillation circuit.

It is important to reduce the noise of the cubic function control voltage at a point B shown in FIG. 15. It is analyzed that the noise at the point B is divided into a noise of a temperature sensor and a noise of a reference voltage. However, in a known circuit configuration, when the circuit is configured by buffering a voltage acquired by dividing a voltage of a regulator by resistance to the reference voltage, a noise of the regulator is generally output as a buffer output. As a result, it is necessary to increase a current so as to reduce the control voltage. Thus, since it is necessary to increase the size of a transistor, it is difficult to decrease the current and the size of the circuit.

FIG. 16 is a diagram illustrating a characteristic of a known cubic function generating circuit. As shown in the figure, a cubic-function voltage output is constituted by the sum of an output of a linear function component and an output of a cubic function component. Here, in a known configuration of the linear function, a slope of approximately −8 mV/° C. is acquired by the temperature sensor. However, a noise caused by the temperature sensor influences a phase noise.

### SUMMARY OF THE INVENTION

The present invention is contrived to solve the above-mentioned problem. An object of the invention is to provide a temperature-compensated crystal oscillator which reduces a noise of an oscillation control voltage.

A temperature-compensated crystal oscillator according to an aspect of the invention includes a quartz vibrator; an amplifier having an oscillation frequency controller; and a temperature compensation circuit of an oscillation frequency of the quartz vibrator, wherein a reference voltage for a compensation voltage of the temperature compensation circuit is generated using a forward voltage of a diode. By this configuration, it is possible to reduce a noise of an oscillation control voltage by using a temperature characteristic and a good noise characteristic as the reference voltage and a temperature sensor.

A temperature-compensated crystal oscillator according to a second aspect of the invention includes a quartz vibrator; an amplifier having an oscillation frequency controller; and a temperature compensation circuit of an oscillation frequency of the quartz vibrator, wherein a compensation voltage of the temperature compensation circuit is divided into a linear-function component and a cubic-function component and is applied to the oscillation frequency controller. By this configuration, it is possible to reduce the noise of the oscillation control voltage by dividing the compensation voltage of the temperature compensation circuit into the linear component and the cubic component and applying the divided compensation voltage to the oscillation frequency controller.

A temperature-compensated crystal oscillator according to a third aspect of the invention includes a quartz vibrator; an amplifier having an oscillation frequency controller; and a temperature compensation circuit of an oscillation frequency of the quartz vibrator, wherein a reference voltage for a compensation voltage of a linear-function component is generated using a forward voltage of a diode when the temperature compensation circuit is constituted by a linear-function component circuit portion and a cubic-function component circuit portion. By this configuration, it is possible to reduce the noise of the oscillation control voltage.

A temperature-compensated crystal oscillator according to a fourth aspect of the invention includes a quartz vibrator; an amplifier having an oscillation frequency controller; and a temperature compensation circuit of an oscillation frequency of the quartz vibrator, wherein a reference voltage for a compensation voltage of a cubic-function component is generated using a forward voltage of a diode when the temperature compensation circuit is constituted by a linear-function component circuit portion and a cubic-function component circuit portion. By this configuration, it is possible to reduce the noise of the oscillation control voltage.

A temperature-compensated crystal oscillator according to a fifth aspect of the invention includes a quartz vibrator; an amplifier having an oscillation frequency controller; and a temperature compensation circuit of an oscillation frequency of the quartz vibrator, wherein a linear-function component and a cubic-function component are generated using a forward voltage of a diode as a reference voltage when a compensation voltage of the temperature compensation circuit is divided into the linear-function component and the cubic-function component and is applied to the oscillation frequency controller. By this configuration, it is possible to reduce the noise of the oscillation control voltage.

In a temperature-compensated crystal oscillator of the invention, it is possible to reduce a noise of an oscillation control voltage.

### BRIEF DESCRIPTION OF THE DRAWINGS

FIG. 1 is a diagram illustrating a linear function generating circuit constituting a temperature compensation circuit in a temperature-compensated crystal oscillator according to the invention.

FIG. 2 is a diagram illustrating a configuration of the linear function generating circuit in the temperature-compensated crystal oscillator according to the invention.

FIG. 3 is a diagram illustrating a configuration of another linear function generating circuit in the temperature-compensated crystal oscillator according to the invention.

FIG. 4 is a diagram illustrating a configuration of a control voltage generating circuit in a temperature-compensated crystal oscillator according to a first embodiment of the invention.

FIG. 5 is a diagram illustrating a configuration of another control voltage generating circuit in the temperature-compensated crystal oscillator according to the first embodiment of the invention.

FIG. 6 is a diagram illustrating a configuration of a voltage controlled oscillator in a temperature-compensated crystal oscillator according to a second embodiment of the invention.

FIG. 7 is a diagram illustrating an f-V characteristic of the voltage controlled oscillator in the temperature-compensated crystal oscillator according to the second embodiment of the invention.

FIG. 8 is a diagram illustrating a characteristic of a linear function control voltage in the temperature-compensated crystal oscillator according to the second embodiment of the invention.

FIG. 9 is a diagram illustrating a characteristic of a cubic function control voltage in the temperature-compensated crystal oscillator according to the second embodiment of the invention.

FIG. 10 is a diagram illustrating a configuration of a control voltage generating circuit in a temperature-compensated crystal oscillator according to a third embodiment of the invention.

FIG. 11 is a diagram illustrating a configuration of a control voltage generating circuit in a temperature-compensated crystal oscillator according to a fourth embodiment of the invention

FIG. 12 is a diagram illustrating a configuration of a control voltage generating circuit in a temperature-compensated crystal oscillator according to a fifth embodiment of the invention.

FIG. 13 is a diagram illustrating the configuration of the control voltage generating circuit in the temperature-compensated crystal oscillator according to the fifth embodiment of the invention.

FIG. 14 is a diagram illustrating an example of a known TCXO.

FIG. 15 is a diagram illustrating another example of the known TCXO.

FIG. 16 is a diagram illustrating a characteristic of a known cubic function generating circuit.

### DESCRIPTION OF THE PREFERRED EMBODIMENTS

Hereinafter, a temperature-compensated crystal oscillator according to an embodiment of the invention will be described with reference to the accompanying drawings. The temperature-compensated crystal oscillator (TCXO) to be described below includes a quartz vibrator, an amplifier having an oscillation frequency controller, and a temperature compensation circuit of an oscillation frequency of the quartz vibrator. The same circuit elements as the known circuit elements are denoted by the same reference numerals.

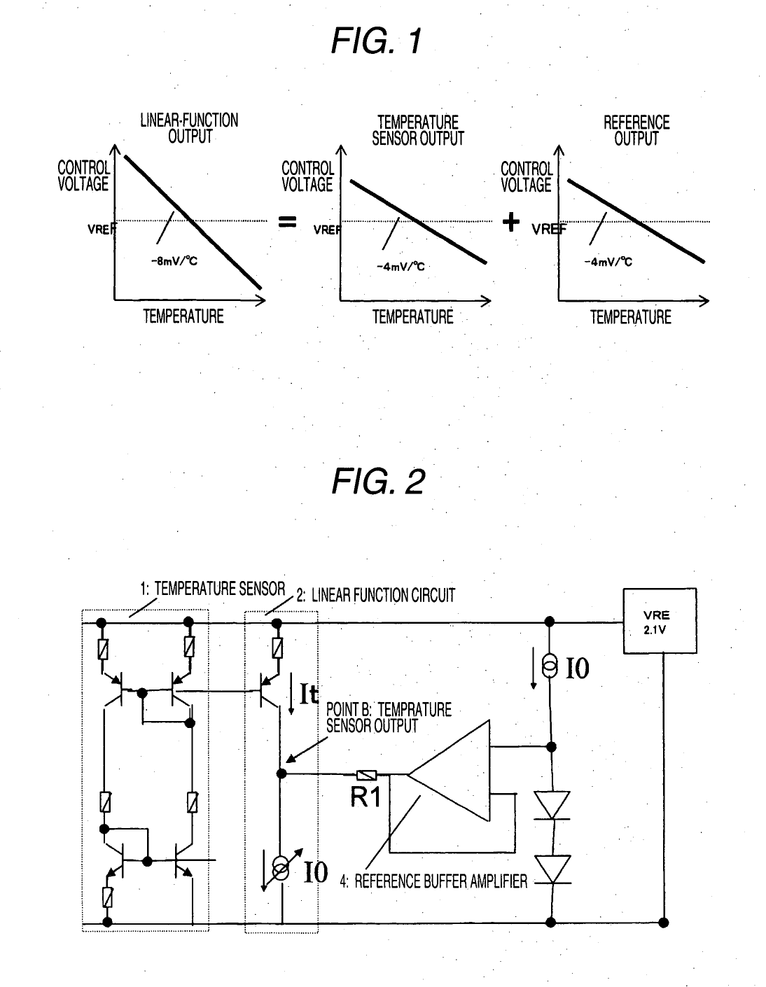

FIG. 1 is a diagram illustrating a linear function generating circuit constituting a temperature compensation circuit in the temperature-compensated crystal oscillator according to the invention. A cubic-function voltages output serving as the control voltage, which is applied to the oscillation frequency controller is constituted by the sum of an output of a linear function component (a linear component) and an output of a cubic function component (a cubic component). In the present embodiment, a linear function is not designed only by a temperature sensor, but it is possible to reduce a noise by using a forward voltage of a diode having a good noise as a reference of the compensation circuit. For example, as shown in FIG. 1, the influence on a temperature sensor resulting in the noise can be reduced by implementing −4 mV of −8 mV with the temperature sensor and implementing the rest −4 mV with two diodes connected in series so as to use the voltage as a reference voltage in comparison with that in the related art. Accordingly, it is possible to reduce the voltage noise.

Hereinafter, a configuration example of the linear function generating circuit generating the linear function shown in FIG. 1 will be described.

FIG. 2 is a diagram illustrating a configuration of the linear function generating circuit in the temperature-compensated crystal oscillator according to the invention. The linear function generating circuit shown in the figure includes a temperature sensor 1 employing a band gap voltage Vt, a linear function circuit 2, a reference buffer amplifier 4, and two diodes connected in series. A general band gap reference circuit is used for the temperature sensor 1. A current (a current proportional to Vt) having a temperature characteristic, which is generated by the general band gap reference circuit is referred to as ‘It’ by using a current mirror of a PNP transistor. A current I0 which does not have the temperature characteristic is configured by a constant current source and the current is adjusted so that the equation of It−I0=0 is satisfied approximately at room temperature. The current of It−I0 is input into a resistance R1 and a characteristic of the linear function is acquired as an output of the linear function generating circuit. Here, an input of the reference buffer amplifier is acquired by two diodes and has a low noise. Moreover, the input of the reference buffer amplifier has a temperature characteristic of −4 mV/OC. Referring to FIG. 1, when −8 mV is generated as described above, it is possible reduce the noise by adding −4 mV of the two diodes to −4 mV generated by (It−I0)R1. Here, R1 can be set to a half of a known resistance.

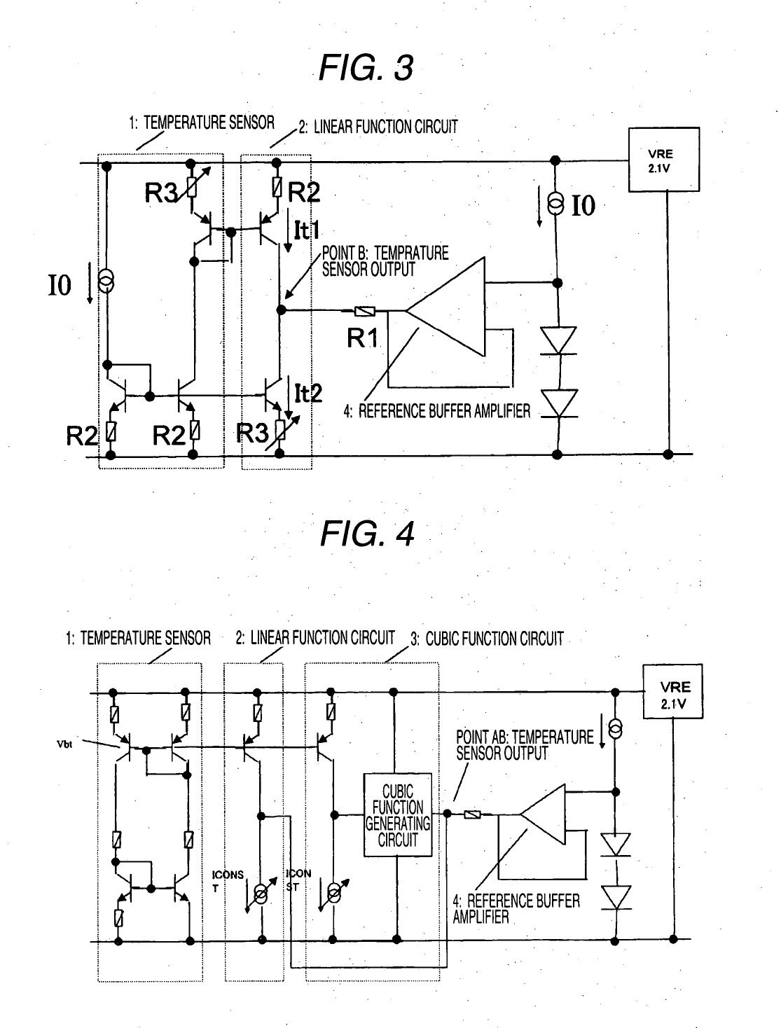

FIG. 3 is a diagram illustrating a configuration of another linear function generating circuit in the temperature-compensated crystal oscillator according to the invention. The linear function generating circuit shown in the figure includes the temperature sensor 1 employing resistors having different temperature characteristics, the linear function circuit 2, the reference buffer amplifier 4, and the two diodes connected in series. The temperature sensor 1 includes a circuit employing a difference between temperature characteristics of resistances R2 and R3. The current I0 which does not have the temperature characteristic is input into an NPN current mirror circuit. At this time, an emitter resistance of the current mirror circuit is different from a diffusion resistance and a polysilicon resistance. For example, when the emitter resistance of a current mirror source is the polysilicon resistance and the emitter resistance of the output of the current mirror circuit is the diffusion resistance, ‘It2’ has a negative temperature characteristic. On the contrary, ‘It1’ has a positive temperature characteristic. An output of the linear function circuit 2 is input to the resistance R1, whereby it is possible to reduce the noise similarly as in FIG. 2.

However, a slope of a cubic function characteristic constituting the cubic-function voltage output with the above-mentioned linear function is a slope of the temperature characteristic different from that of the diode. Accordingly, it is possible to change the slope of the cubic function characteristic to the same slope as the diode by applying an opposite polarity to a variable capacitance element of an oscillation control circuit. That is, in the cubic function characteristic, it is possible to reduce the voltage noise by using a temperature characteristic and a good noise characteristic of the diode, similarly as in the cubic function characteristic.

### First Embodiment

FIG. 4 is a diagram illustrating a configuration of a control voltage generating circuit in the temperature-compensated crystal oscillator according to a first embodiment of the invention. The control voltage generating circuit shown in the figure includes the linear function generating circuit shown in FIG. 3 and the cubic function circuit 3. Reference voltages of the linear function circuit and the cubic function circuit are generated using the forward voltages of the two diodes connected in series. At this time, it is possible to acquire −8 mV/° C. at a point AB and reduce the noise by setting the slope of the linear function circuit to −4 mV/° C. and the temperature characteristic of the reference voltage to −4 mV/° C.

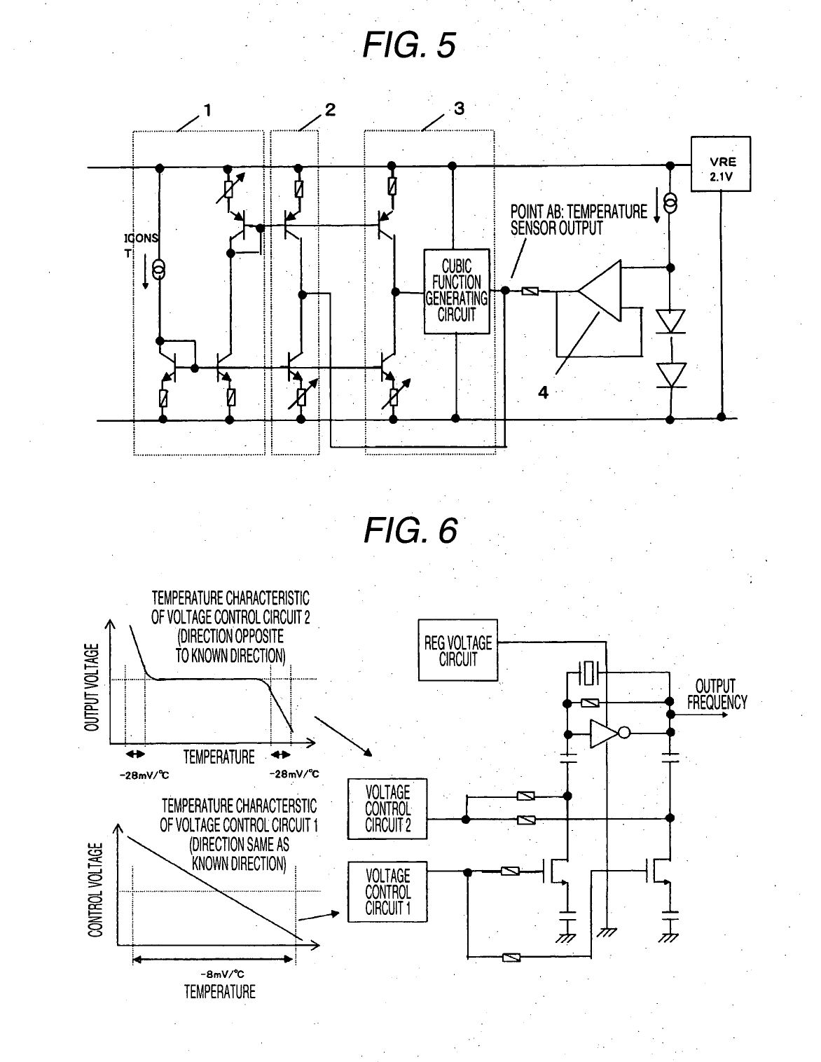

FIG. 5 is a diagram illustrating another control voltage generating circuit of the temperature-compensated crystal oscillator according to the first embodiment of the invention. The control voltage generating circuit shown in the figure includes the linear function generating circuit shown in FIG. 2 and the cubic function circuit 3. The reference voltages of the linear function circuit and the cubic function circuit are generated using the forward voltages of the two diodes connected in series. At this time, it is possible to acquire −8 mV/° C. at a point AB and reduce the noise by setting the slope of the linear function circuit to −4 mV/° C. and the temperature characteristic of the reference voltage to −4 mV/° C.

### Second Embodiment

FIG. 6 is a diagram illustrating a configuration of a voltage controlled oscillator in the temperature-compensated crystal oscillator according to a second embodiment of the invention. The voltage controlled oscillator further includes a capacitor capable of applying the control voltage to a drain as well as a gate of an MOS varactor. As shown in the figure, the control voltage (a compensation voltage) is divided into a linear function component generated by the voltage control circuit 1 and a cubic function component generated by the voltage control circuit 2 and is applied to the oscillation control circuit.

The crystal oscillator shown in FIG. 6 includes an oscillation inverter, a feedback resistor, and a quartz vibrator. The crystal oscillator uses an MOS transistor as a variable capacitor so as to control a frequency of the crystal oscillator and maintains a constant frequency by controlling a gate and a drain of the MOS transistor. It is possible to acquire characteristics shown in the figure by considering the linear component and the cubic component of the control voltage independently. It is possible to reduce a noise of a linear-function voltage by using the diode as described with reference to FIGS. 2 and 3. On the other hand, since a waveform in inputting a cubic-function voltage into the gate is different from a direction of the temperature characteristic of the diode, it is difficult to utilize a low noise characteristic and the temperature characteristic of the diode. The polarity is inverted by inputting the cubic-function voltage into the drain. By this configuration, since the cubic-function voltage has the same direction of the temperature characteristic as the diode, it is possible to reduce the noise by using the diode in a high-low area similar to the linear-function voltage.

As described above, by this configuration, a compensation voltage of the temperature compensation circuit is divided into the linear component and the cubic component and is applied to the oscillation frequency controller, thereby reducing the noise of the oscillation control voltage.

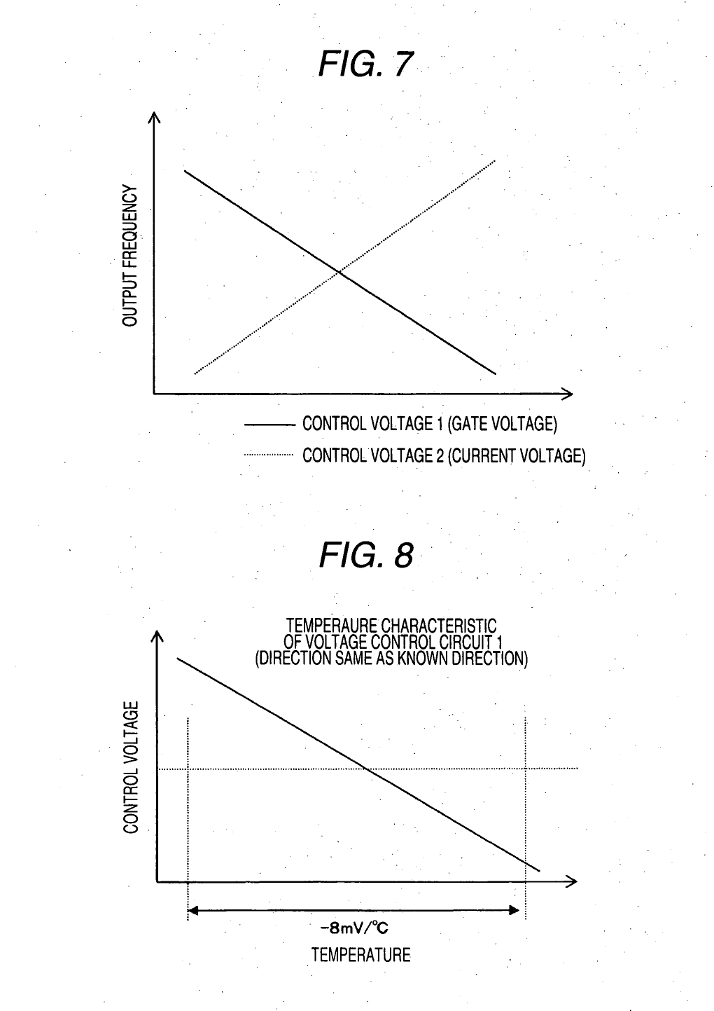

FIG. 7 is a diagram illustrating an f-V characteristic of the voltage controlled oscillator in the temperature-compensated crystal oscillator according to the second embodiment of the invention. FIG. 7 illustrates a change of a frequency f when the gate voltage and the drain voltage of the MOS varactor are independently changed. When the polarity is changed and the slope has an absolute value, it is possible to acquire the same characteristic. In a configuration of the voltage controlled oscillator shown in FIG. 6, the MOS varactor is described, but it is possible to acquire the same characteristic as even in a cathode and the anode of a junction capacitor.

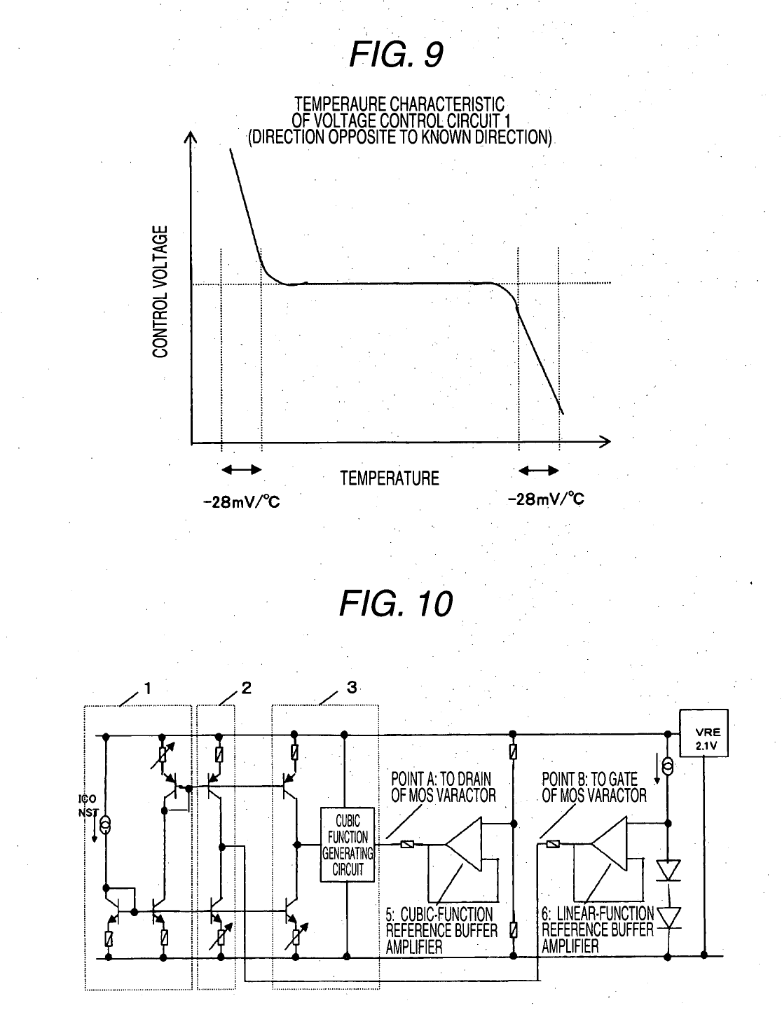

In the known circuit shown in FIG. 14, the control voltage (acquired by synthesizing the linear component and the cubic component) is input into the gate of the MOS transistor. On the other hand, in the configuration of FIG. 6, since the linear component and the cubic component are independently input, the linear component is input into the gate of the known MOS transistor and the cubic component is input into the drain of the known the MOS transistor. As shown in FIGS. 8 and 9, since the known polarity needs to be inverted so that the cubic function characteristic has the same direction as the characteristic of the diode, the cubic function component is input into the drain of the MOS transistor.

FIG. 8 is a diagram illustrating the characteristic of the linear function control voltage in the temperature-compensated crystal oscillator according to the second embodiment of the invention. As shown in the figure, the linear-function control voltage has the same characteristic as the known control voltage (see FIG. 16). On the other hand, FIG. 9 is a diagram illustrating the cubic function control voltage of the temperature-compensated crystal oscillator according to the second embodiment of the invention. As shown in the figure, the cubic-function control voltage has a characteristic opposite to the known control voltage (see FIG. 16). By this configuration, it is possible to apply a bias to nodes of the linear component and the cubic component, which have different polarities of the MOS varactor. At this time, it is possible to configure the cubic function circuit by using the known function generating circuit disclosed in Patent Document 1 described above.

### Third Embodiment

FIG. 10 is a diagram illustrating a configuration of the control voltage generating circuit in the temperature-compensated crystal oscillator according to a third embodiment of the invention. An example in which the resistor is used as a humidity sensor is illustrated in FIG. 10. The linear function and the cubic function are configured on the basis of independent reference voltages. The reference of the linear function is configured using the diode. The reference of the cubic function is configured by resistance dividing. By this configuration, it is possible to reduce the noise of the control voltage at the linear function side.

### Fourth Embodiment

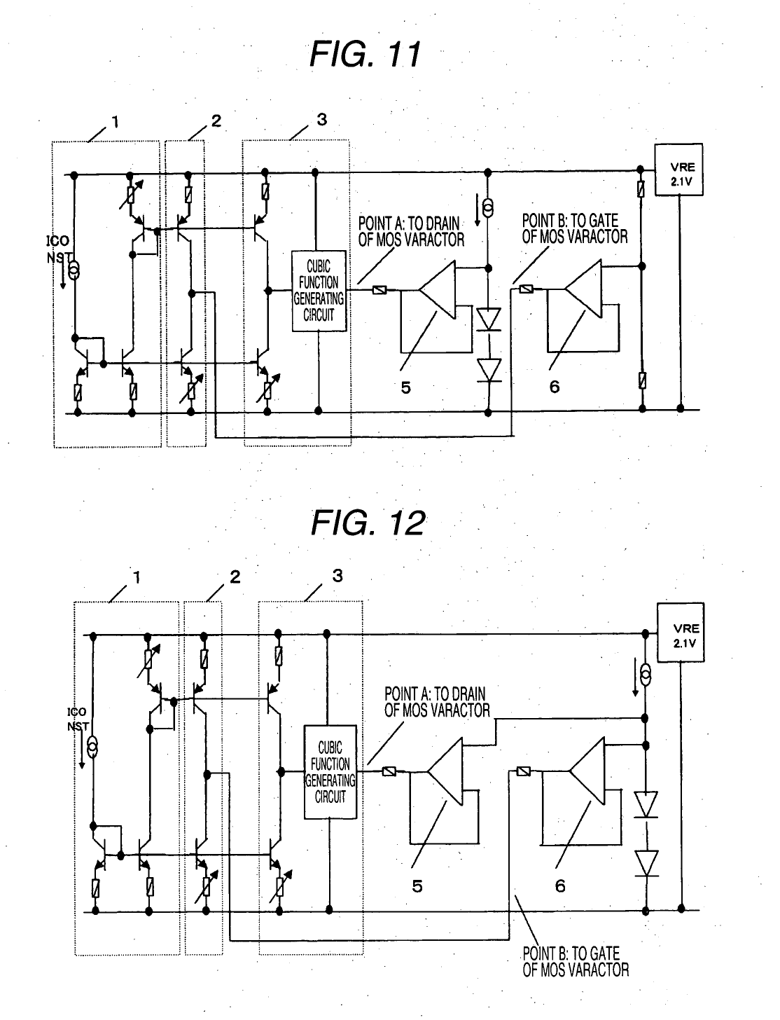

FIG. 11 is a diagram illustrating of the control voltage generating circuit in the temperature-compensated crystal oscillator according to a fourth embodiment of the invention. An example in which the resistor is used as the temperature sensor is illustrated in FIG. 11. The linear function and the cubic function are configured on the basis of the independent reference voltages. The reference of the cubic function is configured using the diode. The reference of the linear function is configured by resistance dividing. By this configuration, it is possible to reduce the noise of the control voltage at the cubic function side.

### Fifth Embodiment

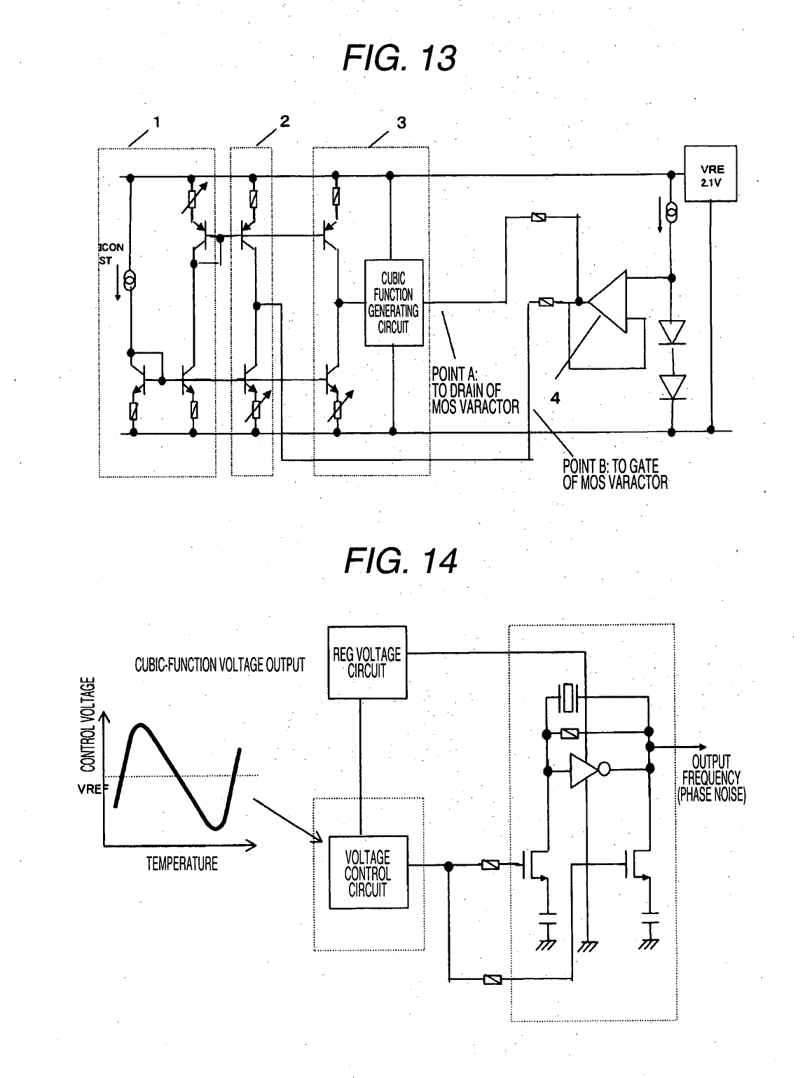

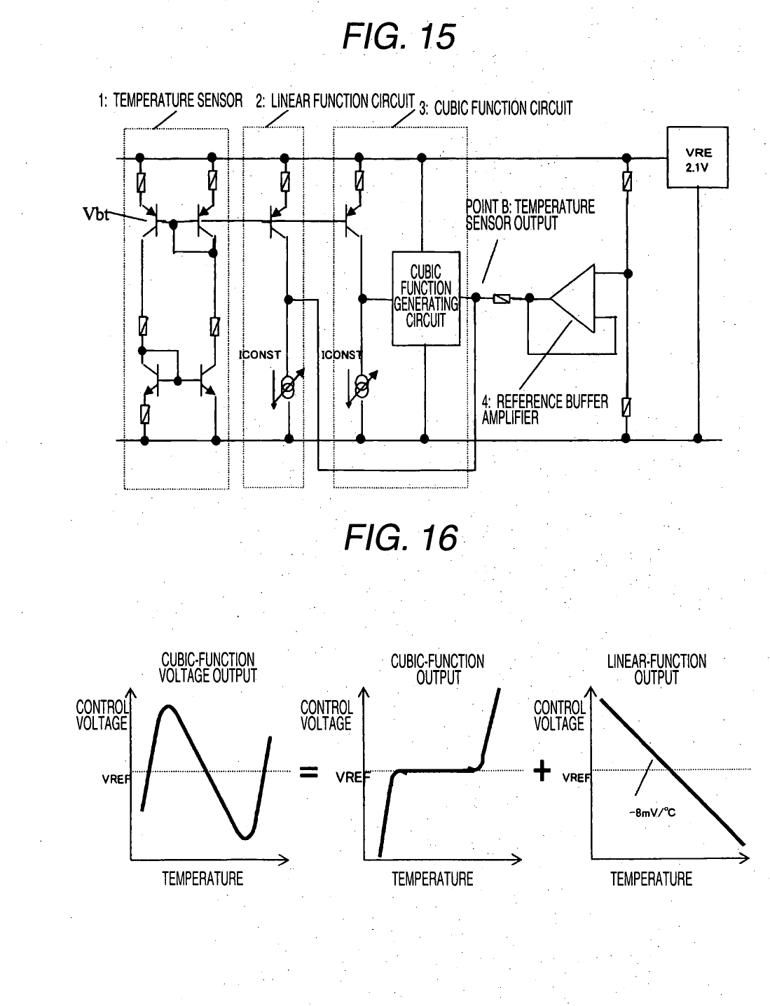

FIGS. 12 and 13 are diagrams illustrating the configuration of the control voltage generating circuit in the temperature-compensated crystal oscillator according to a fifth embodiment of the invention. Examples in which the resistor is used as the humidity sensor are illustrated in FIGS. 12 and 13. The linear function and the cubic function are configured on the basis of the independent reference voltages. The references of the linear function and the cubic function are configured using the diode. By this configuration, it is possible to reduce the noise of the control voltages at the linear function side and the cubic function side. FIG. 12 is a circuit diagram illustrating a configuration provided with buffer amplifiers and FIG. 13 is a circuit diagram illustrating a configuration provided with only one buffer amplifier.

A temperature-compensated crystal oscillator according to the invention has advantage of reducing a noise of an oscillation control voltage and is useful for a humidity-compensated crystal oscillator employing a voltage controlled capacitance element.

What is claimed is:

1. A temperature-compensated crystal oscillator, comprising:
a quartz vibrator;
an amplifier having an oscillation frequency controller; and
a temperature compensation circuit of an oscillation frequency of the quartz vibrator,
wherein a reference voltage for a compensation voltage of the temperature compensation circuit is generated using a forward voltage of a diode.

2. A temperature-compensated crystal oscillator, comprising:
a quartz vibrator;
an amplifier having an oscillation frequency controller; and
a temperature compensation circuit of an oscillation frequency of the quartz vibrator,
wherein a compensation voltage of the temperature compensation circuit is divided into a linear-function component and a cubic-function component and is applied to the oscillation frequency controller.

3. A temperature-compensated crystal oscillator, comprising:
a quartz vibrator;
an amplifier having an oscillation frequency controller; and
a temperature compensation circuit of an oscillation frequency of the quartz vibrator,
wherein a reference voltage for a compensation voltage of a linear-function component is generated using a forward voltage of a diode when the temperature compensation circuit is constituted by a linear-function component circuit portion and a cubic-function component circuit portion.

4. A temperature-compensated crystal oscillator, comprising:
a quartz vibrator;
an amplifier having an oscillation frequency controller; and
a temperature compensation circuit of an oscillation frequency of the quartz vibrator,
wherein a reference voltage for a compensation voltage of a cubic-function component is generated using a forward voltage of a diode when the temperature compensation circuit is constituted by a linear-function component circuit portion and a cubic-function component circuit portion.

5. A temperature-compensated crystal oscillator, comprising:
a quartz vibrator;
an amplifier having an oscillation frequency controller; and
a temperature compensation circuit of an oscillation frequency of the quartz vibrator,
wherein a linear-function component and a cubic-function component are generated using a forward voltage of a diode as a reference voltage when a compensation voltage of the temperature compensation circuit is divided into the linear-function component and the cubic-function component and is applied to the oscillation frequency controller.
